(19) United States
(12) Patent Application Publication
(10) Pub. No.: US 2019/0214329 A1
(43) Pub. Date: Jul. 11, 2019

(54) LIQUID HEAT DISSIPATION SYSTEM

(71) Applicant: ASIA VITAL COMPONENTS CO., LTD., New Taipei City (TW)

(72) Inventor: Wen-Ji Lan, New Taipei City (TW)

(21) Appl. No.: 15/867,703

(22) Filed: Jan. 11, 2018

(51) Int. Cl. H01L 23/473; G06F 1/20; H01L 23/467; H05K 7/20

(52) U.S. Cl. CPC H01L 23/473; H05K 7/20218; H01L 23/467; G06F 1/20

(57) ABSTRACT

A liquid heat dissipation system includes: a first thermal module having a first inlet, a first outlet and a first module liquid-containing space for a working fluid to flow, the first inlet and the first outlet communicating with the first module liquid-containing space, whereby the working fluid flows through the first inlet into the first module liquid-containing space; and a second thermal module having a second inlet, a second outlet and a second module liquid-containing space for the working fluid to flow. The second inlet and the second outlet communicate with the second module liquid-containing space, whereby the working fluid flows through the second inlet into the second module liquid-containing space. The first outlet is mated with the second inlet. The first inlet is connected to a heat-exchange module. The second outlet is connected to a pump. The heat-exchange module and the pump are connected to each other.

### BACKGROUND OF THE INVENTION

### 1. Field of the Invention

The present invention relates generally to a liquid heat dissipation system, and more particularly to a liquid heat dissipation system, which is expandable to enhance the heat dissipation effect.

### 2. Description of the Related Art

In various industrial fields or daily life, it often takes place that the temperature in a specific space is too high. For example, the processor or the graphics card chip of an electronic apparatus will generate high heat when working. The high heat must be conducted out and dissipated in time. Otherwise, the temperature will rapidly rise to cause some ill affection to the electronic apparatus, for example, deterioration of the working efficiency or damage of the component.

In order to lower the working temperature of the heat source, a water-cooling device has been developed to conduct the heat and lower the temperature. The water-cooling device includes a water-cooling radiator connected to a water pump and a water-cooling head via two water conduits. The water-cooling head is in contact with a heat source. The water pump serves to drive the water-cooling liquid (or so-called working fluid) to flow to the water-cooling radiator to dissipate the heat and continuously circulate the working fluid to cool the heat generation component and quickly dissipate the heat. Please refer to FIG. 1. The conventional water-cooling radiator 1 is composed of multiple radiating fins 11, multiple straight flat tubes 12 and two lateral water tanks 13. The radiating fins 11 are disposed between the straight flat tubes 12. The two lateral water tanks 13, the radiating fins 11 and two sides of the straight flat tubes 12 are soldered with each other so that the two lateral water tanks 13, the radiating fins 11 and the straight flat tubes 12 are connected to form the water-cooling radiator 1. A water inlet 131 and a water outlet 132 are disposed on one of the lateral water tanks 13. The water inlet 131 and the water outlet 132 are respectively connected with two opposite water conduits (not shown).

The cooling efficiency of the water-cooling radiator is determined by the staying time of the water-cooling liquid. The longer the water-cooling liquid stays in the water-cooling radiator, the lower the temperature of the water is. Reversely, the shorter the water-cooling liquid stays in the water-cooling radiator, the higher the temperature of the water is. However, the water-cooling head has a fixed heat dissipation ability (staying time of water-cooling liquid). In case the heat dissipation ability is insufficient, it is necessary to replace the water-cooling radiator with a larger one to prolong the staying time of water-cooling liquid.

However, the replacement of the water-cooling radiator with a larger one for enhancing the heat dissipation ability is not applicable to some situation that necessitates heat dissipation. For example, a computer case has a limited internal space in which many other components are also arranged. With respect to the limited internal space, it is impractical to replace the water-cooling radiator with a larger one to enhancing the heat dissipation efficiency.

In conclusion, the conventional water-cooling radiator has the following shortcomings:

1. The heat dissipation ability is limited due to the size of the water-cooling radiator.

2. The room occupied by the water-cooling radiator is larger so that the site to which the water-cooling radiator is applicable to quite limited.

It is therefore tried by the applicant to provide a liquid heat dissipation system to eliminate the above shortcomings of the conventional water-cooling radiator.

### SUMMARY OF THE INVENTION

It is therefore a primary object of the present invention to provide a liquid heat dissipation system in which the number of the thermal modules can be adjusted according to the required heat dissipation ability.

It is a further object of the present invention to provide the above liquid heat dissipation system in which the relative positions between every thermal module and every liquid-containing main body can be previously adjusted and changed according to the size of the arrangement space.

To achieve the above and other objects, the liquid heat dissipation system of the present invention includes: a first thermal module having a first inlet, a first outlet and a first module liquid-containing space for a working fluid to flow through, the first inlet and the first outlet communicating with the first module liquid-containing space, whereby the working fluid flows through the first inlet into the first module liquid-containing space; and a second thermal module having a second inlet, a second outlet and a second module liquid-containing space for the working fluid to flow through. The second inlet and the second outlet communicate with the second module liquid-containing space. The first outlet is mated with the second inlet. The working fluid flows from the first inlet into the first thermal module and flows from the second outlet out of the second thermal module.

In the above liquid heat dissipation system, the first thermal module includes a first liquid-containing main body, a second liquid-containing main body and at least one first communication tube, two ends of the first communication tube respectively communicating with the first and second liquid-containing main bodies, the first and second liquid-containing main bodies being up and down vertically arranged or left and right horizontally arranged, the first and second liquid-containing main bodies and the first communication tube being made of gold, silver, copper, iron, titanium, aluminum or an alloy material thereof.

In the above liquid heat dissipation system, the first liquid-containing main body has a first liquid chamber and the second liquid-containing main body has a second liquid chamber, the first module liquid-containing space including the first liquid chamber, the second liquid chamber and an internal space of the first communication tube, the first inlet being disposed on the first liquid-containing main body, the first outlet being selectively disposed on the first liquid-containing main body or the second liquid-containing main body.

In the above liquid heat dissipation system, the second thermal module includes a third liquid-containing main body, a fourth liquid-containing main body and at least one second communication tube, two ends of the second communication tube respectively communicating with the third and fourth liquid-containing main bodies, the third and fourth liquid-containing main bodies being up and down vertically arranged or left and right horizontally arranged, the third and fourth liquid-containing main bodies and the second communication tube being made of gold, silver, copper, iron, titanium, aluminum or an alloy material thereof.

In the above liquid heat dissipation system, the third liquid-containing main body has a third liquid chamber and the fourth liquid-containing main body has a fourth liquid chamber, the second module liquid-containing space including the third liquid chamber, the fourth liquid chamber and an internal space of the second communication tube, the second inlet being disposed on the third liquid-containing main body, the second outlet being selectively disposed on the third liquid-containing main body or the fourth liquid-containing main body.

In the above liquid heat dissipation system, the first and second thermal modules are up and down vertically arranged or left and right horizontally arranged or misaligned from each other.

In the above liquid heat dissipation system, a first module communication tube is disposed between the first outlet and the second inlet, a first end of the first module communication tube being connected with the first outlet, a second end of the first module communication tube being connected with the second inlet, a first radiating fin assembly being disposed on outer side of the first thermal module, a second radiating fin assembly being disposed on outer side of the second thermal module, at least one fan being disposed on a lateral side of the first and second radiating fin assemblies, the first inlet being connected to a water outlet of a cooling module, the second outlet being connected to a water inlet of a pump component, a water inlet of the cooling module being connected to a water outlet of the pump component.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective view of a conventional water-cooling radiator;

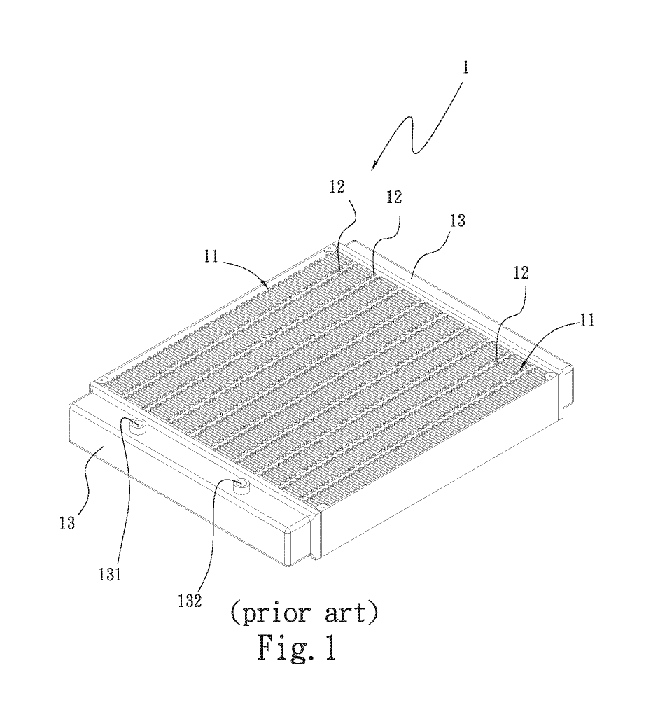

FIG. 2A is a perspective exploded view of a first embodiment of the liquid heat dissipation system of the present invention;

FIG. 2B is a perspective assembled view of the first embodiment of the liquid heat dissipation system of the present invention;

FIG. 2C is a sectional view of the first embodiment of the liquid heat dissipation system of the present invention;

FIG. 3A is a perspective exploded view of a second embodiment of the liquid heat dissipation system of the present invention;

FIG. 3B is a perspective assembled view of the second embodiment of the liquid heat dissipation system of the present invention;

FIG. 4A is a perspective exploded view of a third embodiment of the liquid heat dissipation system of the present invention;

FIG. 4B is a perspective assembled view of the third embodiment of the liquid heat dissipation system of the present invention;

FIG. 5A is a perspective exploded view of a fourth embodiment of the liquid heat dissipation system of the present invention;

FIG. 5B is a perspective assembled view of the fourth embodiment of the liquid heat dissipation system of the present invention;

FIG. 6A is a perspective exploded view of a fifth embodiment of the liquid heat dissipation system of the present invention;

FIG. 6B is a perspective assembled view of the fifth embodiment of the liquid heat dissipation system of the present invention;

FIG. 6C is a sectional view of the fifth embodiment of the liquid heat dissipation system of the present invention;

FIG. 7A is a perspective exploded view of a sixth embodiment of the liquid heat dissipation system of the present invention;

FIG. 7B is a perspective assembled view of the sixth embodiment of the liquid heat dissipation system of the present invention;

FIG. 8A is a perspective exploded view of a seventh embodiment of the liquid heat dissipation system of the present invention; and

FIG. 8B is a perspective assembled view of the seventh embodiment of the liquid heat dissipation system of the present invention.

### DETAILED DESCRIPTION OF THE PREFERRED EMBODIMENTS

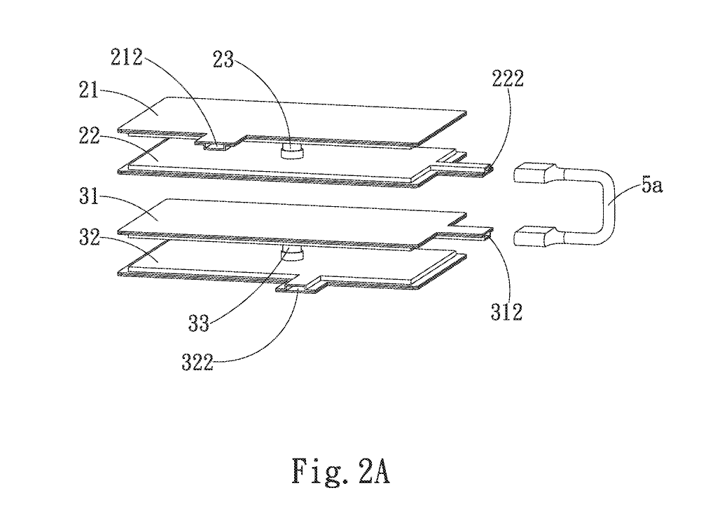

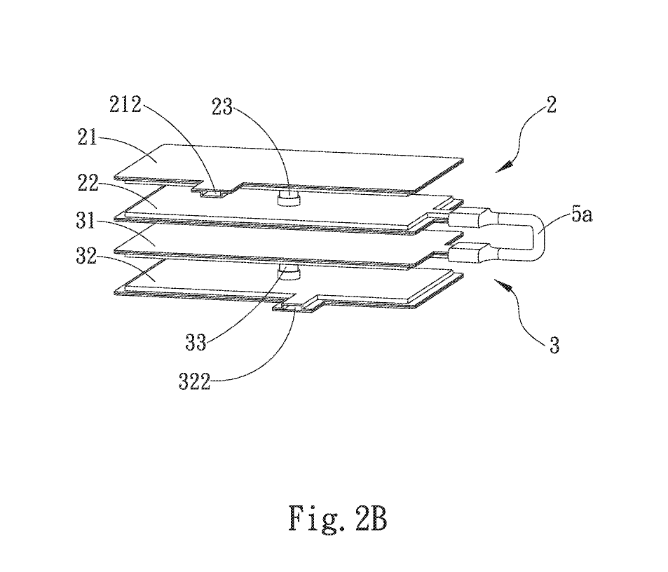

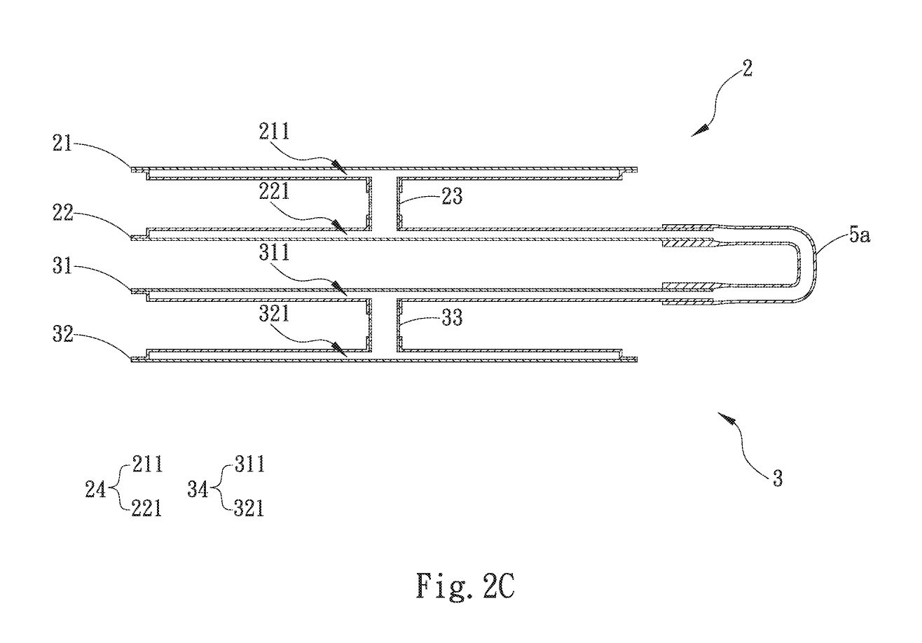

Please refer to FIGS. 2A, 2B and 2C. FIG. 2A is a perspective exploded view of a first embodiment of the liquid heat dissipation system of the present invention. FIG. 2B is a perspective assembled view of the first embodiment of the liquid heat dissipation system of the present invention. FIG. 2C is a sectional view of the first embodiment of the liquid heat dissipation system of the present invention. According to the first embodiment, the liquid heat dissipation system of the present invention includes a first thermal module 2, a second thermal module 3 and a first module communication tube 5a. The first thermal module 2 is positioned above the second thermal module 3. Two ends of the first module communication tube 5a respectively communicate with the first and second thermal modules 2, 3 to form an up and down vertical structure.

The first thermal module 2 includes a first liquid-containing main body 21, a second liquid-containing main body 22 and a first communication tube 23. The first liquid-containing main body 21 is composed of two plate members mated with each other to define a first liquid chamber 211. A liquid flow way (not shown) is disposed in the first liquid-containing main body 21 for prolonging the staying time of a working fluid. The second liquid-containing main body 22 is composed of two plate members mated with each other to define a second liquid chamber 221. A liquid flow way (not shown) is disposed in the second liquid-containing main body 22 for prolonging the staying time of the working fluid. The first liquid-containing main body 21 is positioned above the second liquid-containing main body 22 at an interval. Two ends of the first communication tube 23 are respectively connected with the first liquid-containing main body 21 and the second liquid-containing main body 22. A first inlet 212 is disposed on the first liquid-containing main body 21 and a first outlet 222 is disposed on the second liquid-containing main body 22. The first thermal module 2 has a first module liquid-containing space 24. The first module liquid-containing space 24 includes the first liquid chamber 211, the second liquid chamber 221 and the internal space of the first communication tube 23.

The second thermal module 3 includes a third liquid-containing main body 31, a fourth liquid-containing main body 32 and a second communication tube 33. The third liquid-containing main body 31 is composed of two plate members mated with each other to define a third liquid chamber 311. A liquid flow way (not shown) is disposed in the third liquid-containing main body 31 for prolonging the staying time of the working fluid. The fourth liquid-containing main body 32 is composed of two plate members mated with each other to define a fourth liquid chamber 321. A liquid flow way (not shown) is disposed in the fourth liquid-containing main body 32 for prolonging the staying time of the working fluid. The third liquid-containing main body 31 is positioned above the fourth liquid-containing main body 32 at an interval. Two ends of the second communication tube 33 are respectively connected with the third liquid-containing main body 31 and the fourth liquid-containing main body 32. A second inlet 312 is disposed on the third liquid-containing main body 31 and a second outlet 322 is disposed on the fourth liquid-containing main body 32. The second thermal module 3 has a second module liquid-containing space 34. The second module liquid-containing space 34 includes the third liquid chamber 311, the fourth liquid chamber 321 and the internal space of the second communication tube 33.

A first end of the first module communication tube 5a is connected with the first outlet 222. A second end of the first module communication tube 5a is connected with the second inlet 312. The first communication tube 23 of the first thermal module 2 is coaxial with the second communication tube 33 of the second thermal module 3.

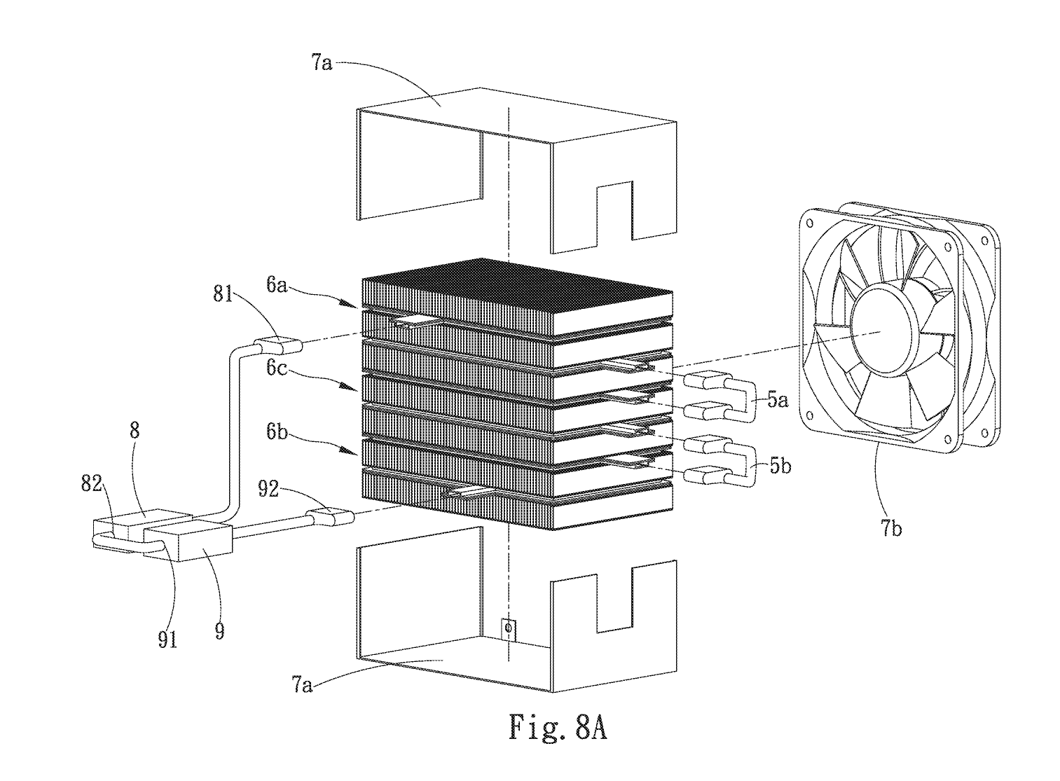

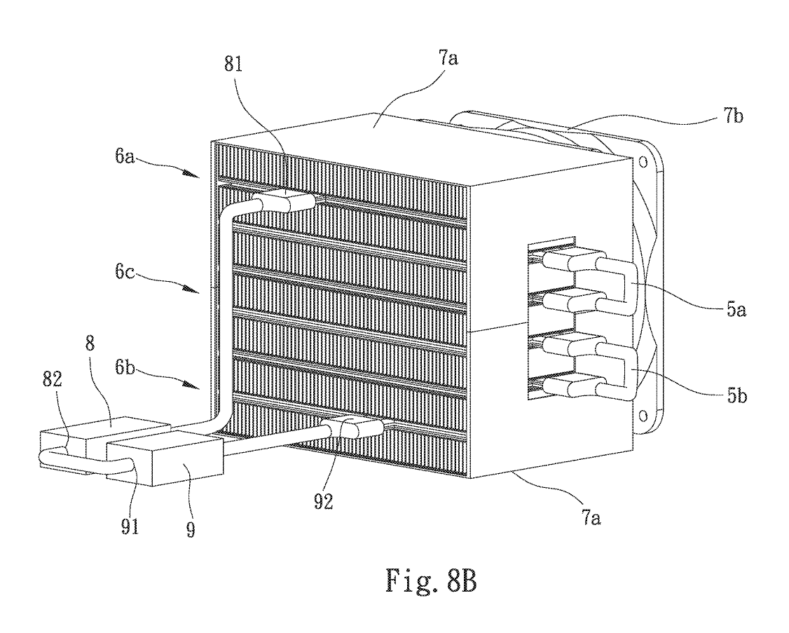

Please refer to FIGS. 2A˜2C and FIGS. 8A and 8B. When a cooling module 8 heat-exchanges with a heat source, the working fluid absorbs the heat and flows toward the first thermal module 2. Then the working fluid flows from the first inlet 212 into the first liquid-containing main body 21. The working fluid flows along the liquid flow way (not shown) disposed in the first liquid-containing main body 21 and passes through the first communication tube 23 into the second liquid-containing main body 22. Then the working fluid flows along the liquid flow way (not shown) disposed in the second liquid-containing main body 22 and flows out of the first thermal module 2 from the first outlet 222. The working fluid then passes through the first module communication tube 5a and flows from the second inlet 312 into the third liquid-containing main body 31. Then the working fluid flows along the liquid flow way (not shown) disposed in the third liquid-containing main body 31 and passes through the second communication tube 33 into the fourth liquid-containing main body 32. Then the working fluid flows along the liquid flow way (not shown) disposed in the fourth liquid-containing main body 32 and flows out of the second thermal module 3 from the second outlet 322. After the working fluid leaves the second thermal module 3, the temperature of the working fluid is lowered. The working fluid with lowered temperature flows into a pump component 9 for pressurizing and driving the working fluid into the cooling module 8. In the cooling module 8, the working fluid again heat-exchanges with the heat source to continue the heat dissipation circulation.

The liquid flow ways (not shown) disposed in the liquid-containing main bodies can be designed according to the required heat dissipation ability (the staying time of the working fluid). Also, the number of the first and second communication tubes 23, 33 can be adjusted and changed according to the design of the liquid flow ways (not shown) and the positions of the inlets and outlets of each thermal module. In this embodiment, the first and second thermal modules 2, 3 are up and down vertically arranged, whereby the first and second thermal modules 2, 3 can be applied to a vertically narrow and elongated site.

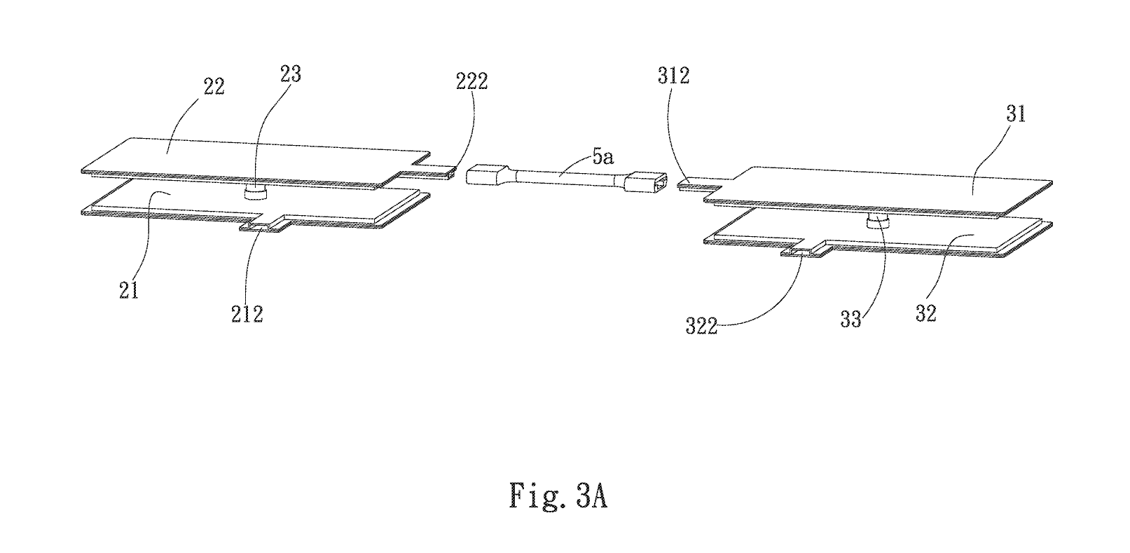

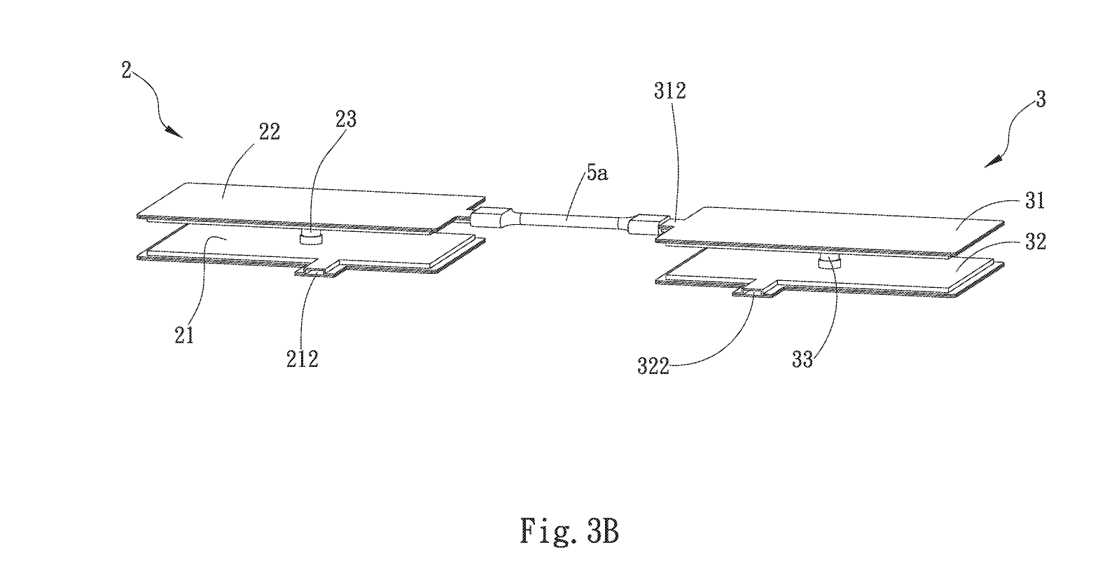

Please now refer to FIGS. 3A and 3B. FIG. 3A is a perspective exploded view of a second embodiment of the liquid heat dissipation system of the present invention. FIG. 3B is a perspective assembled view of the second embodiment of the liquid heat dissipation system of the present invention. The second embodiment is partially identical to the first embodiment in structure and thus will not be redundantly described hereinafter. The second embodiment is mainly different from the first embodiment in that the first and second thermal modules 2, 3 are left and right horizontally arranged. The first liquid-containing main body 21 of the first thermal module 2 is positioned under the second liquid-containing main body 22. The first liquid-containing main body 21 is in parallel to the fourth liquid-containing main body 32. The second liquid-containing main body 22 is in parallel to the third liquid-containing main body 31. In this embodiment, the first and second thermal modules 2, 3 are left and right horizontally arranged, whereby the first and second thermal modules 2, 3 can be applied to a horizontally narrow and elongated site.

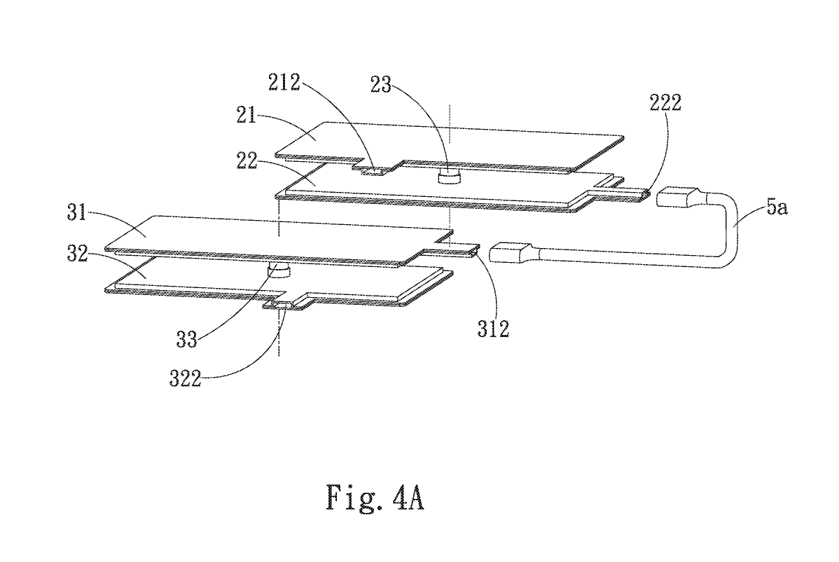

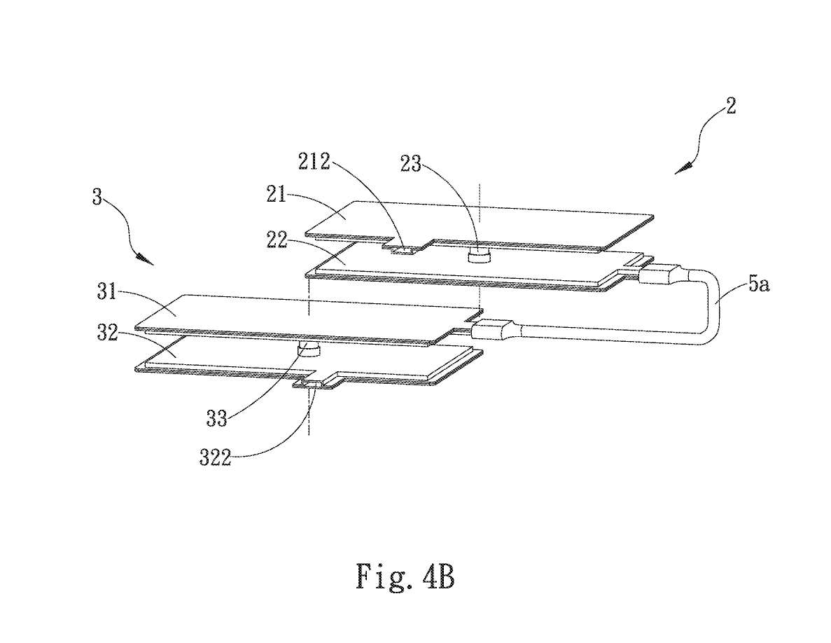

Please now refer to FIGS. 4A and 4B. FIG. 4A is a perspective exploded view of a third embodiment of the liquid heat dissipation system of the present invention. FIG. 4B is a perspective assembled view of the third embodiment of the liquid heat dissipation system of the present invention. The third embodiment is partially identical to the first embodiment in structure and thus will not be redundantly described hereinafter. The third embodiment is mainly different from the first embodiment in that the first and second thermal modules 2, 3 are up and down vertically arranged and back and forth and left and right misaligned from each other. The first communication tube 23 of the first thermal module 2 is not coaxial with the second communication tube 33 of the second thermal module 3. The first thermal module 2 is positioned above the second thermal module 3. In this embodiment, the first and second thermal modules 2, 3 are back and forth and left and right misaligned from each other, whereby the first and second thermal modules 2, 3 can be applied to an irregular site with a lopsided space.

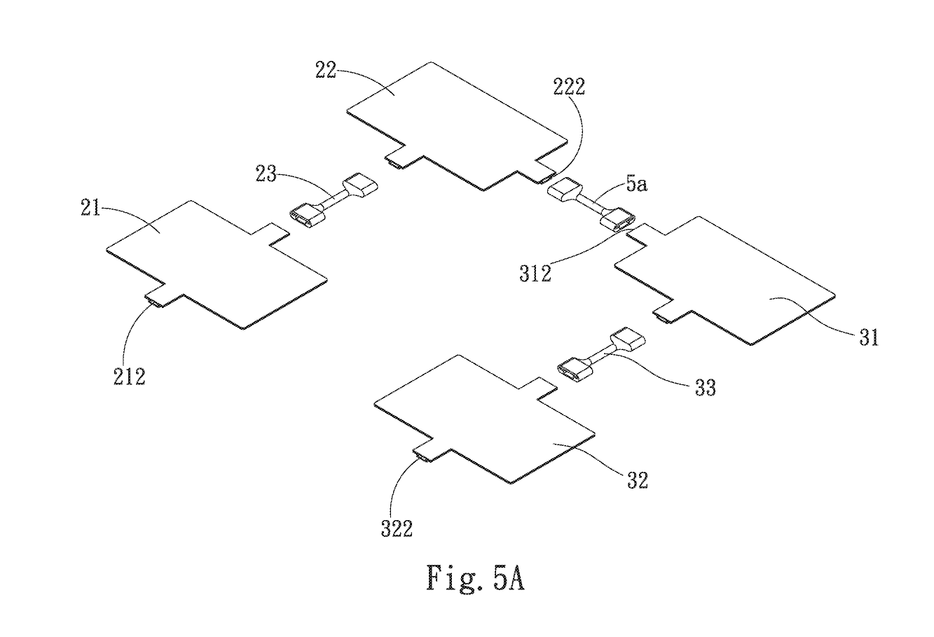

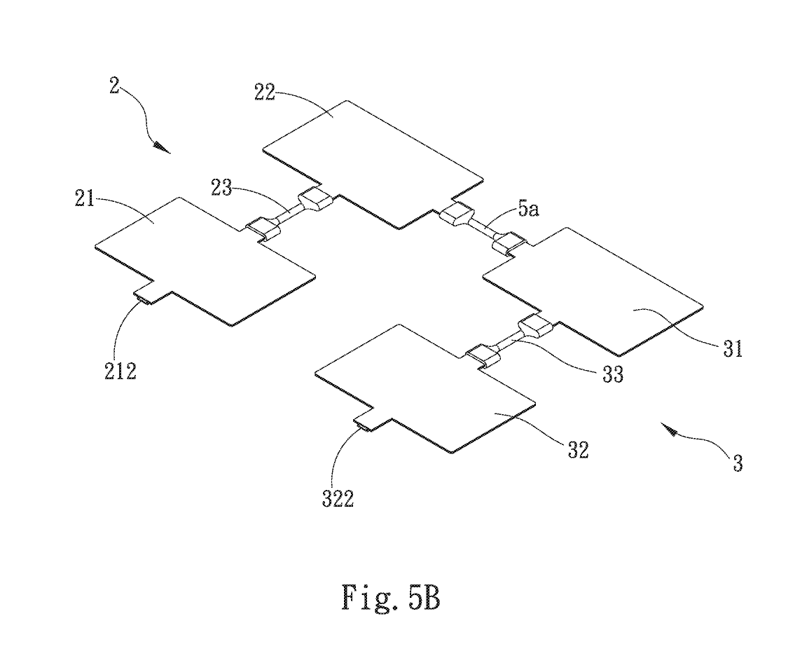

Please now refer to FIGS. 5A and 5B. FIG. 5A is a perspective exploded view of a fourth embodiment of the liquid heat dissipation system of the present invention. FIG. 5B is a perspective assembled view of the fourth embodiment of the liquid heat dissipation system of the present invention. The fourth embodiment is partially identical to the first embodiment in structure and thus will not be redundantly described hereinafter. The fourth embodiment is mainly different from the first embodiment in that the first and second thermal modules 2, 3 are left and right horizontally arranged. The first liquid-containing main body 21, the second liquid-containing main body 22 and the first communication tube 23 of the first thermal module 2 are positioned on the same level. The third liquid-containing main body 31, the fourth liquid-containing main body 32 and the second communication tube 33 of the second thermal module 3 are positioned on the same level. The first and second communication tubes 23, 33 have an elongated flat form. In this embodiment, every thermal module and every liquid-containing main body are positioned on the same level without height difference. In this case, the working fluid can more smoothly flow and the liquid heat dissipation system can be applied to a site with a wider heat dissipation space.

It is described in the first to fourth embodiments that the relative positions of the respective thermal modules can be changed as necessary. Furthermore, the liquid-containing main bodies of the thermal modules can be selectively up and down vertically arranged or left and right horizontally arranged according to the use requirement. Also, the number of the liquid-containing main bodies and the number of the communication tubes of the thermal modules can be increased or decreased according to the requirement. In addition, the liquid flow ways (not shown) disposed in the liquid-containing main bodies can be freely modified. Moreover, the positions of the communication tubes can be adjusted in accordance with the design of the liquid flow ways (not shown). It is only necessary to keep each thermal module having an outlet and an inlet and two thermal modules are connected with each other via a module communication tube. All the above pertain to the scope of the present invention.

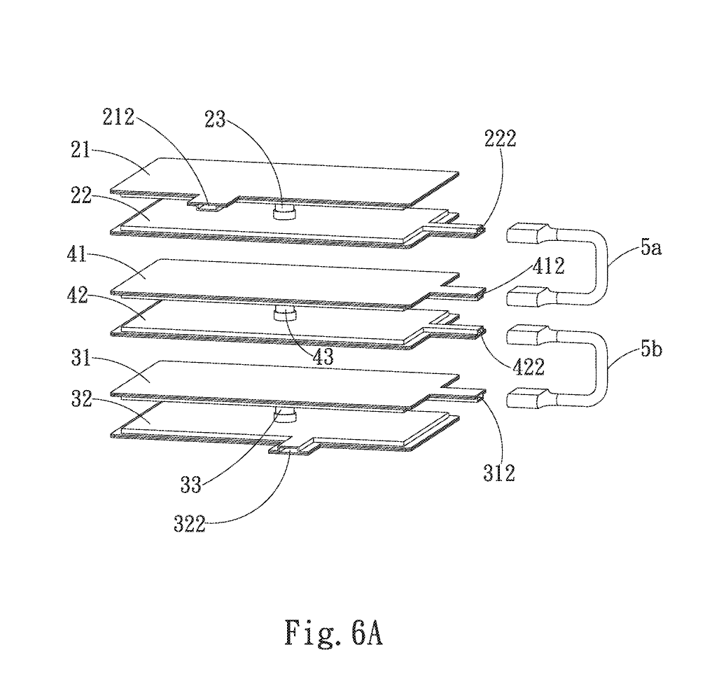

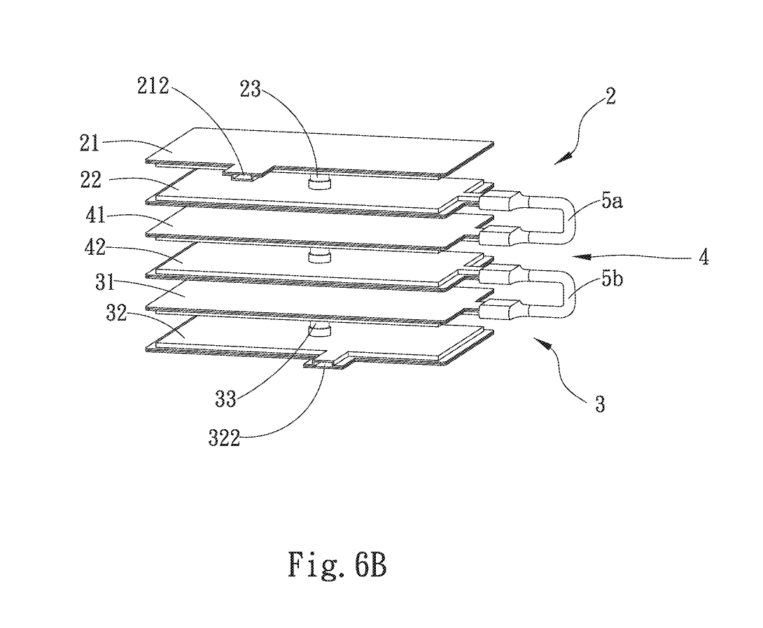

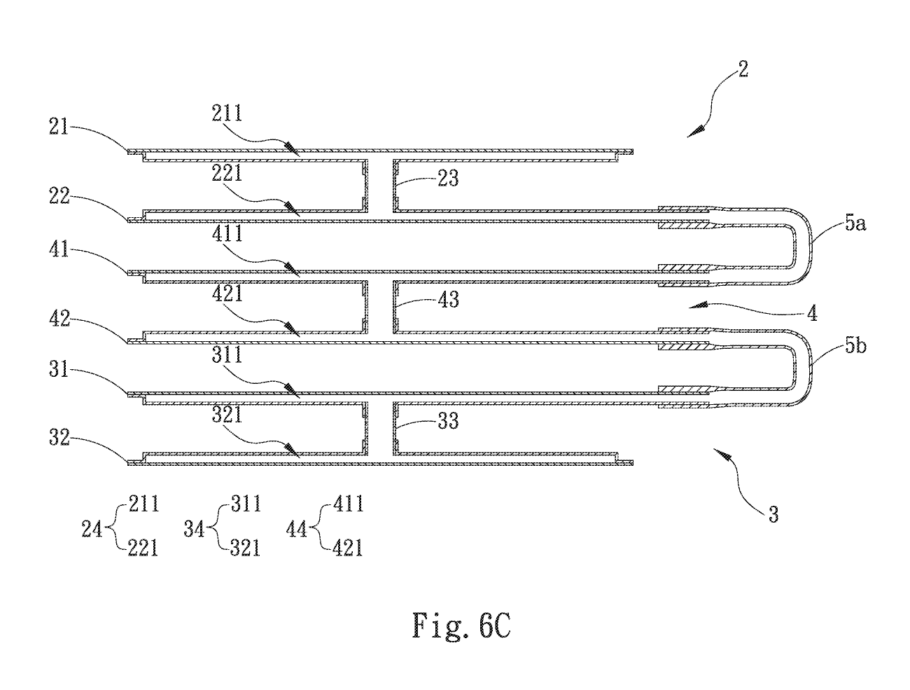

Please now refer to FIGS. 6A, 6B and 6C. FIG. 6A is a perspective exploded view of a fifth embodiment of the liquid heat dissipation system of the present invention. FIG. 6B is a perspective assembled view of the fifth embodiment of the liquid heat dissipation system of the present invention. FIG. 6C is a sectional view of the fifth embodiment of the liquid heat dissipation system of the present invention. The fifth embodiment is partially identical to the first embodiment in structure and thus will not be redundantly described hereinafter. The fifth embodiment is mainly different from the first embodiment in that the fifth embodiment further includes a third thermal module 4. The third thermal module 4 includes a fifth liquid-containing main body 41, a sixth liquid-containing main body 42 and a third communication tube 43. The fifth liquid-containing main body 41 is composed of two plate members mated with each other to define a fifth liquid chamber 411. A liquid flow way (not shown) is disposed in the fifth liquid-containing main body 41 for prolonging the staying time of the working fluid. The sixth liquid-containing main body 42 is composed of two plate members mated with each other to define a sixth liquid chamber 421. A liquid flow way (not shown) is disposed in the sixth liquid-containing main body 42 for prolonging the staying time of the working fluid. The fifth liquid-containing main body 41 is positioned above the sixth liquid-containing main body 42 at an interval. Two ends of the third communication tube 43 are respectively connected with the fifth liquid-containing main body 41 and the sixth liquid-containing main body 42. A third inlet 412 is disposed on the fifth liquid-containing main body 41 and a third outlet 422 is disposed on the sixth liquid-containing main body 42. The third thermal module 4 has a third module liquid-containing space 44. The third module liquid-containing space 44 includes the fifth liquid chamber 411, the sixth liquid chamber 421 and the internal space of the third communication tube 43.

The third thermal module 4 is disposed between the first and second thermal modules 2, 3. The first, second and third thermal modules 2, 3, 4 form an up and down vertical structure. The first, second and third communication tubes 23, 33, 43 are coaxial with each other. A first end of the first module communication tube 5a is connected with the first outlet 222. A second end of the first module communication tube 5a is connected with the third inlet 412. A first end of the second module communication tube 5b is connected with the third outlet 422. A second end of the second module communication tube 5b is connected with the second inlet 312.

Please now refer to FIGS. 6A-6C and FIGS. 8A and 8B. When the cooling module 8 heat-exchanges with the heat source, the working fluid absorbs the heat and flows toward the first thermal module 2. Then the working fluid flows from the first inlet 212 into the first liquid-containing main body 21 and passes through the first communication tube 23 into the second liquid-containing main body 22. Then the working fluid flows out from the first outlet 222. The working fluid then passes through the first module communication tube 5a and flows from the third inlet 412 into the fifth liquid-containing main body 41. Then the working fluid passes through the third communication tube 43 into the sixth liquid-containing main body 42. Then, the working fluid flows out from the third outlet 422. Then, the working fluid passes through the second module communication tube 5b and flows from the second inlet 312 into the third liquid-containing main body 31. Then the working fluid passes through the second communication tube 33 into the fourth liquid-containing main body 32. Then the working fluid flows out from the second outlet 322. After the working fluid leaves the second thermal module 3, the temperature of the working fluid is lowered. The working fluid with lowered temperature flows into the pump component 9 for pressurizing and driving the working fluid into the cooling module 8. In the cooling module 8, the working fluid again heat-exchanges with the heat source to continue the heat dissipation circulation.

In this embodiment, the third thermal module 4 is additionally disposed between the first and second thermal modules 2, 3 so that the heat dissipation ability of the entire heat dissipation system is enhanced. The passing time of the working fluid through the entire heat dissipation system is prolonged (enters from the first inlet 212 and leaves from the second outlet 322) so that the temperature of the working fluid can be more fully lowered.

In this embodiment, the first, second and third thermal modules 2, 3, 4 are up and down vertically arranged. However, in practice, with reference to the modifications of the second, third and fourth embodiments, the first, second and third thermal modules 2, 3, 4 can be also such as left and right horizontally arranged, up and down vertically arranged and back and forth and left and right misaligned from each other or totally horizontally arranged or arranged in over two manners. For example, the first and third thermal modules 2, 4 are up and down vertically arranged, while the third and the second thermal modules 4, 3 are left and right horizontally arranged, whereby the entire system has an L-shaped form. Accordingly, the liquid heat dissipation system of the present invention can be freely modified in accordance with the space planning.

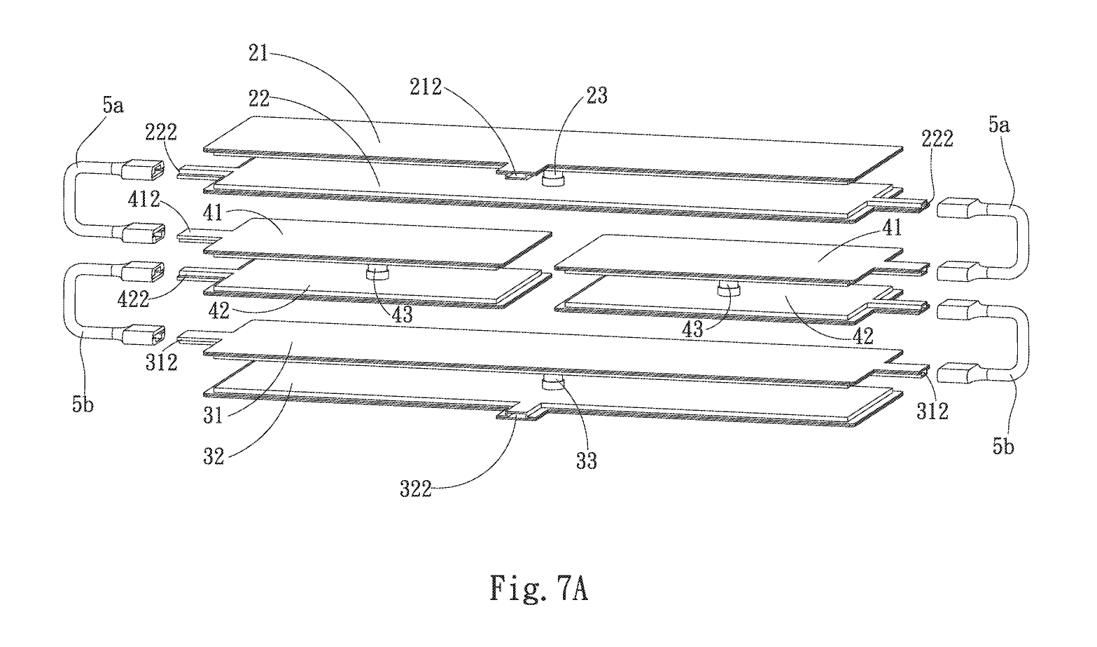

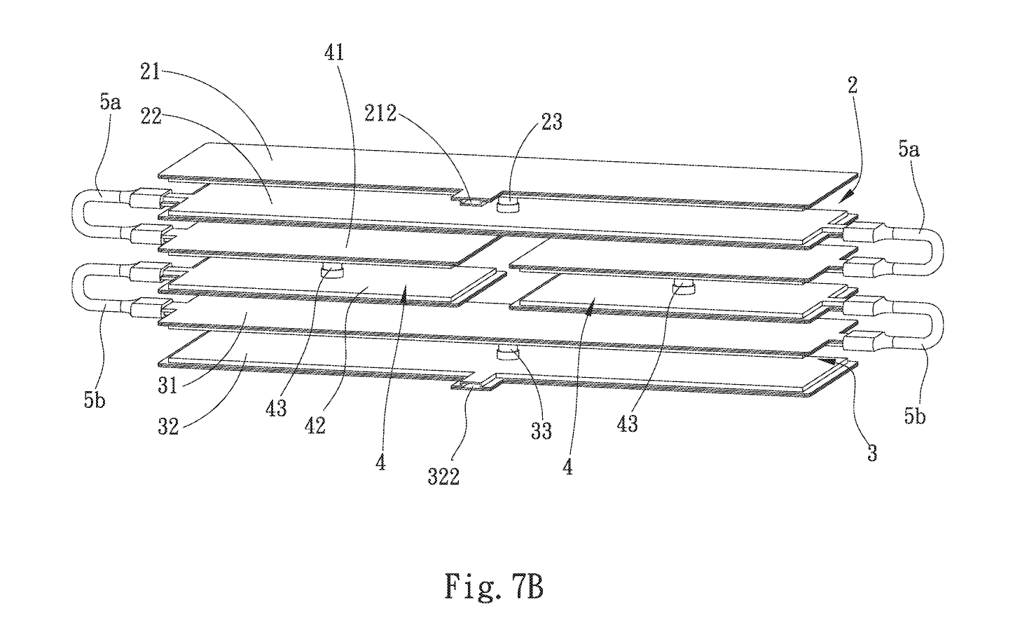

Please now refer to FIGS. 7A and 7B. FIG. 7A is a perspective exploded view of a sixth embodiment of the liquid heat dissipation system of the present invention. FIG. 7B is a perspective assembled view of the sixth embodiment of the liquid heat dissipation system of the present invention. The sixth embodiment is partially identical to the fifth embodiment in structure and thus will not be redundantly described hereinafter. The sixth embodiment is mainly different from the fifth embodiment in that the sixth embodiment includes two third thermal modules 4. The second liquid-containing main body 22 has two first outlets 222 and the third liquid-containing main body 31 has two second inlets 312. The area of the plane face of the fifth and sixth liquid-containing main bodies 41, 42 is smaller than that of the first, second, third and fourth liquid-containing main bodies 21, 22, 31, 32.

In this embodiment, the first, second and third thermal modules 2, 3, 4 are up and down vertically arranged. However, in practice, with reference to the modifications of the second, third and fourth embodiments, the first, second and third thermal modules 2, 3, 4 can be otherwise arranged. In addition, the sizes of the respective thermal modules can be changed (not limited to that the sizes of the first and second thermal modules 2 and 3 are equal to each other and larger than the size of the third thermal module 4). Accordingly, the liquid heat dissipation system of the present invention can be used in a limited lopsided space to enhance the heat dissipation ability of the liquid heat dissipation system of the present invention.

Please now refer to FIGS. 8A and 8B. FIG. 8A is a perspective exploded view of a seventh embodiment of the liquid heat dissipation system of the present invention. FIG. 8B is a perspective assembled view of the seventh embodiment of the liquid heat dissipation system of the present invention. The seventh embodiment is partially identical to the fifth embodiment in structure and thus will not be redundantly described hereinafter. The seventh embodiment is mainly different from the fifth embodiment in that a first radiating fin assembly 6a is disposed on outer side of the first thermal module 2. A second radiating fin assembly 6b is disposed on outer side of the second thermal module 3 and a third radiating fin assembly 6c is disposed on outer side of the third thermal module 4. At least one fan 7b is disposed on a lateral side of the first, second and third thermal modules 2, 3, 4. The first, second and third radiating fin assemblies 6a, 6b, 6c are received in a protection case 7a.

The first inlet 212 is connected to a water outlet 81 of the cooling module 8. The second outlet 322 is connected to a water inlet 92 of the pump component 9. A water inlet 82 of the cooling module 8 is connected to a water outlet 91 of the pump component 9.

The cooling module 8 is in contact with a heat source to absorb the heat, whereby the temperature of the working fluid is raised. The pump component 9 serves to drive the working fluid to flow, whereby the working fluid within the entire heat dissipation system will be sequentially circulated through the cooling module 8, all the thermal modules and the pump component 9. The working fluid flows out from the water outlet 81 of the cooling module 8 carries heat (at high temperature). The working fluid flows through the thermal modules, whereby the heat of the working fluid is outward dissipated from the radiating fin assemblies and exhausted to external space by the fan 7b (to lower the temperature). Then the working fluid without heat flows from the water inlet 92 of the pump component 9 into the pump component 9 to continue the heat dissipation circulation.

The above radiating fin assemblies, the protection case 7a, the fan 7b, the cooling module 8 and the pump component 9 can be freely applied to any of the above embodiments and other not shown modified embodiments. These components only need to be adjusted in accordance with the arrangements of the embodiments (such as the profile of the protection case 7a, the size of the fan 7b, etc.)

In addition, in the above embodiments, the first liquid-containing main body 21 has only one first inlet 212 and the fourth liquid-containing main body 32 has only one second outlet 322. However, according to the number of the connected cooling module 8 and the pump component 9, the number of the first inlet 212 and the number of the second outlet 322 can be increased. In other words, the liquid heat dissipation system of the present invention can be commonly applied to multiple heat sources to achieve the object of heat dissipation.

Moreover, the arrangement of the inlet and outlet of every thermal module are not limited That is, the inlet and outlet can be freely disposed on the same side or different sides. In addition, the configuration of the liquid-containing main body can be freely modified. For example, the liquid-containing main body can have a right polygonal shape or a circular shape. The two liquid-containing main bodies of each thermal module are unnecessary to have equal sizes. Accordingly, the liquid heat dissipation system of the present invention can be more diversely applied to various sites.

In conclusion, the present invention has the following advantages:
1. The relative position between the thermal modules can be freely changed in accordance with the requirement of the use site.
2. The relative position between the liquid-containing main bodies of each thermal module can be freely changed in accordance with the requirement of the use site.
3. The number of the thermal modules can be increased to enhance the heat dissipation ability.
4. The positions of the inlet and outlet can be freely adjusted in accordance with the requirement of the use site.
5. The liquid heat dissipation system of the present invention can be commonly applied to multiple heat sources.

The present invention has been described with the above embodiments thereof and it is understood that many changes and modifications in such as the form or layout pattern or practicing step of the above embodiments can be carried out without departing from the scope and the spirit of the invention that is intended to be limited only by the appended claims.

What is claimed is:

1. A liquid heat dissipation system comprising:
a first thermal module having a first inlet, a first outlet and a first module liquid-containing space for a working fluid to flow through, the first inlet and the first outlet communicating with the first module liquid-containing space; and
a second thermal module having a second inlet, a second outlet and a second module liquid-containing space for the working fluid to flow through, the second inlet and the second outlet communicating with the second module liquid-containing space, the first outlet being mated with the second inlet, whereby the working fluid flows from the first inlet into the first thermal module and flows from the second outlet out of the second thermal module.

2. The liquid heat dissipation system as claimed in claim 1, wherein the first thermal module includes a first liquid-containing main body, a second liquid-containing main body and at least one first communication tube, two ends of the first communication tube respectively communicating with the first and second liquid-containing main bodies, the first and second liquid-containing main bodies being up and down vertically arranged or left and right horizontally arranged, the first and second liquid-containing main bodies and the first communication tube being made of gold, silver, copper, iron, titanium, aluminum or an alloy material thereof.

3. The liquid heat dissipation system as claimed in claim 2, wherein the first liquid-containing main body has a first liquid chamber and the second liquid-containing main body has a second liquid chamber, the first module liquid-containing space including the first liquid chamber, the second liquid chamber and an internal space of the first communication tube, the first inlet being disposed on the first liquid-containing main body, the first outlet being selectively disposed on the first liquid-containing main body or the second liquid-containing main body.

4. The liquid heat dissipation system as claimed in claim 1, wherein the second thermal module includes a third liquid-containing main body, a fourth liquid-containing main body and at least one second communication tube, two ends of the second communication tube respectively communicating with the third and fourth liquid-containing main bodies, the third and fourth liquid-containing main bodies being up and down vertically arranged or left and right horizontally arranged, the third and fourth liquid-containing main bodies and the second communication tube being made of gold, silver, copper, iron, titanium, aluminum or an alloy material thereof.

5. The liquid heat dissipation system as claimed in claim 4, wherein the third liquid-containing main body has a third liquid chamber and the fourth liquid-containing main body has a fourth liquid chamber, the second module liquid-containing space including the third liquid chamber, the fourth liquid chamber and an internal space of the second communication tube, the second inlet being disposed on the third liquid-containing main body, the second outlet being selectively disposed on the third liquid-containing main body or the fourth liquid-containing main body.

6. The liquid heat dissipation system as claimed in claim 1, wherein the first and second thermal modules are up and down vertically arranged or left and right horizontally arranged or misaligned from each other.

7. The liquid heat dissipation system as claimed in claim 1, wherein a first module communication tube is disposed between the first outlet and the second inlet, a first end of the first module communication tube being connected with the first outlet, a second end of the first module communication tube being connected with the second inlet, a first radiating fin assembly being disposed on outer side of the first thermal module, a second radiating fin assembly being disposed on outer side of the second thermal module, at least one fan being disposed on a lateral side of the first and second radiating fin assemblies, the first inlet being connected to a water outlet of a cooling module, the second outlet being connected to a water inlet of a pump component, a water inlet of the cooling module being connected to a water outlet of the pump component.

8. A liquid heat dissipation system comprising:
a first thermal module having at least one first inlet, at least one first outlet and a first module liquid-containing space for a working fluid to flow through, the first inlet and the first outlet communicating with the first module liquid-containing space;
a second thermal module having at least one second inlet, at least one second outlet and a second module liquid-containing space for the working fluid to flow through, the second inlet and the second outlet communicating with the second module liquid-containing space; and
at least one third thermal module having at least one third inlet, at least one third outlet and a third module liquid-containing space for a working fluid to flow through, the third inlet and the third outlet communicating with the third module liquid-containing space, the first outlet being mated with the third inlet, the third outlet being mated with the second inlet, whereby the working fluid flows from the first inlet into the first thermal module and then into the third thermal module and then flows from the second outlet out of the second thermal module.

9. The liquid heat dissipation system as claimed in claim 8, wherein the first thermal module includes a first liquid-containing main body, a second liquid-containing main body and at least one first communication tube, two ends of the first communication tube respectively communicating with the first and second liquid-containing main bodies, the first and second liquid-containing main bodies being up and down vertically arranged or left and right horizontally arranged, the first and second liquid-containing main bodies and the first communication tube being made of gold, silver, copper, iron, titanium, aluminum or an alloy material thereof.

10. The liquid heat dissipation system as claimed in claim 9, wherein the first liquid-containing main body has a first liquid chamber and the second liquid-containing main body has a second liquid chamber, the first module liquid-containing space including the first liquid chamber, the second liquid chamber and an internal space of the first communication tube, the first inlet being disposed on the first liquid-containing main body, the first outlet being selectively disposed on the first liquid-containing main body or the second liquid-containing main body.

11. The liquid heat dissipation system as claimed in claim 8, wherein the second thermal module includes a third liquid-containing main body, a fourth liquid-containing main body and at least one second communication tube, two ends of the second communication tube respectively communicating with the third and fourth liquid-containing main bodies, the third and fourth liquid-containing main bodies being up and down vertically arranged or left and right horizontally arranged, the third and fourth liquid-containing main bodies and the second communication tube being made of gold, silver, copper, iron, titanium, aluminum or an alloy material thereof.

12. The liquid heat dissipation system as claimed in claim 11, wherein the third liquid-containing main body has a third liquid chamber and the fourth liquid-containing main body has a fourth liquid chamber, the second module liquid-containing space including the third liquid chamber, the fourth liquid chamber and an internal space of the second communication tube, the second inlet being disposed on the third liquid-containing main body, the second outlet being selectively disposed on the third liquid-containing main body or the fourth liquid-containing main body.

13. The liquid heat dissipation system as claimed in claim 8, wherein the third thermal module includes a fifth liquid-containing main body, a sixth liquid-containing main body and at least one third communication tube, two ends of the third communication tube respectively communicating with the fifth and sixth liquid-containing main bodies, the fifth and sixth liquid-containing main bodies being up and down vertically arranged or left and right horizontally arranged, the fifth and sixth liquid-containing main bodies and the third communication tube being made of gold, silver, copper, iron, titanium, aluminum or an alloy material thereof.

14. The liquid heat dissipation system as claimed in claim 13, wherein the fifth liquid-containing main body has a fifth liquid chamber and the sixth liquid-containing main body has a sixth liquid chamber, the third module liquid-containing space including the fifth liquid chamber, the sixth liquid chamber and an internal space of the third communication tube, the third inlet being disposed on the fifth liquid-containing main body, the third outlet being selectively disposed on the fifth liquid-containing main body or the sixth liquid-containing main body.

15. The liquid heat dissipation system as claimed in claim 8, wherein the first, second and third thermal modules are up and down vertically arranged or left and right horizontally arranged or misaligned from each other.

16. The liquid heat dissipation system as claimed in claim 8, wherein a first module communication tube is disposed between the first outlet and the third inlet and a second module communication tube is disposed between the third outlet and the second inlet, a first end of the first module communication tube being connected with the first outlet, a second end of the first module communication tube being connected with the third inlet, a first end of the second module communication tube being connected with the third outlet, a second end of the second module communication tube being connected with the second inlet.

17. The liquid heat dissipation system as claimed in claim 8, wherein a first radiating fin assembly is disposed on outer side of the first thermal module, a second radiating fin assembly being disposed on outer side of the second thermal module, a third radiating fin assembly being disposed on outer side of the third thermal module, at least one fan being disposed on a lateral side of the first, second and third radiating fin assemblies.

18. The liquid heat dissipation system as claimed in claim 8, wherein the first inlet is connected to a water outlet of a cooling module, the second outlet being connected to a water inlet of a pump component, a water inlet of the cooling module being connected to a water outlet of the pump component.
